(19) United States
(12) Patent Application Publication
(10) Pub. No.: US 2024/0379893 A1
(43) Pub. Date: Nov. 14, 2024

(54) Semiconductor detector device

(71) Applicant: Teknologian tutkimuskeskus VTT Oy, Espoo (FI)

(72) Inventors: Markku Kainlauri, Espoo (FI); Olli-Pekka Kilpi, Espoo (FI); Aapo Varpula, Espoo (FI); Mika Prunnila, Espoo (FI)

(21) Appl. No.: 18/696,377

(22) PCT Filed: Sep. 30, 2022
(86) PCT No.: PCT/FI2022/050653

§ 371 Date: Mar. 28, 2024

(30) Foreign Application Priority Data
Oct. 1, 2021 (FI) 20216021

(51) Int. Cl. H01L 31/112; H01L 31/0216; H01L 31/0224

(52) U.S. Cl. CPC H01L 31/112; H01L 31/02161; H01L 31/022408

(57) ABSTRACT

According to an example aspect of the present invention, there is provided semiconductor radiation detectors, such as photodetectors, with a low amount of material in the radiation/photon entrance window and minimal doping of semiconductor substrate. More specifically, an induced junction based on electrically polarized materials is utilized.

### FIELD

The present invention relates to semiconductor detectors, such as radiation detectors and photodetectors.

### BACKGROUND

In an electromagnetic wave detector, semiconductor material is generally used as an electromagnetic wave detection layer.

A photodiode is a semiconductor device with a P-N junction that converts photons (or light) into electrical current. The Player has an abundance of holes (positive), and the N layer has an abundance of electrons (negative). Photodiodes can be manufactured from a variety of materials including, but not limited to, Silicon, Germanium, and Indium Gallium Arsenide. Each material uses different properties for cost benefits, increased sensitivity, wavelength range, low noise levels, or even response speed.

Photodetectors may be based on different technologies, including photodiodes (PN junction, PIN junction, Schottky diode). Conventional PN junction radiation detectors and photodetectors are based on PN junctions which lie rather deep below the surface of the detector. This leaves an electrically dead layer between the entrance window and the PN junction of the detector, thereby reducing the electrical output signal of the detector via absorption of radiation signal within the dead layer. Furthermore, in conventional PN junction based detectors, the moderate or heavy doping of the top part of the PN junction increases the Auger recombination in this region giving rise to lower quantum efficiency and output signal. The signal reduction via absorption is especially detrimental in detection of UV and X-ray photons, and gamma rays. The signal reduction associated with the excess depth of the PN junction and doping (via Auger recombination) is crucial in UV detectors as UV photons have very low absorption lengths.

Shallow PN junctions, which lie very near the surface of the detector, are especially needed in detection of high energy photons (such as UV and X-ray radiation) as any photo-electrically dead layer between the entrance window and the PN junction is minimal. Induced junctions provide efficient ways to realize shallow PN junctions, and they are also efficient in detection of lower-energy photons.

Existing induced junction detectors are based on deposition of material with inducing surface charge on the detector surface. The features of the inducing layer are determined by the material properties of this layer, which are limited by the available materials, and deposition and post-deposition processes. Typically thermally grown silicon oxide and ALD grown Al2O3 are used. The available charge range is limited for these materials, leading to less strong induced junctions and, therefore, device performance. For example, the publication of Dönsberg et al.: “Predictable quantum efficient detector based on n-type silicon photodiodes”, 2017 Metrologia 54 821, which is incorporated by reference herein, describes a Al2O3(Al₂O₃, aluminium oxide)-based induced junction detector.

### SUMMARY OF THE INVENTION

The scope of the invention is defined in the independent claims. Some embodiments are defined in the dependent claims.

According to a first aspect of the present invention, there is provided a radiation detector, comprising: a substrate made of semiconductor material; an electric field generating layer on a first face of the substrate, the electric field generating layer inducing electric field into the substrate for forming an inversion layer in the substrate; a first electrical contact on the first face of the substrate and next to the electric field generating layer; and a second electrical contact on the second face of the substrate and opposite to the electric field generating layer; wherein the electric field generating layer comprises a dielectric layer with a polarization and/or charge for inducing the electric field, wherein the dielectric layer comprises at least one of: ferroelectric material, electric material, ferroelectric material.

According to a second aspect of the present invention, there is provided a method of manufacturing any one of the radiation detectors disclosed herein. According to further aspects of the second aspect, the manufacturing may comprise single-sided processing or double-sided processing.

### BRIEF DESCRIPTION OF THE DRAWINGS

FIGS. 1A and 1B illustrate sectional or side views of a semiconductor detector device structure in accordance with at least some embodiments;

FIG. 2 illustrates a sectional or side view of a semiconductor detector device structure in accordance with at least some embodiments;

FIG. 3 illustrates a sectional or side view of a semiconductor detector device structure in accordance with at least some embodiments;

FIG. 4 illustrates a sectional or side view of a semiconductor detector device structure in accordance with at least some embodiments;

FIG. 5 illustrates a sectional or side view of a semiconductor detector device structure in accordance with at least some embodiments.

### EMBODIMENTS

The embodiments of the present disclosure provide semiconductor radiation detectors, such as photodetectors, with low amount of material in the radiation/photon entrance window and minimal doping of semiconductor substrate. More specifically, the embodiments of the present disclosure utilize an induced junction based on electrically polarized and charged materials. Compared to existing induced junction devices, this approach allows stronger inducing charges to be obtained, which leads to improved performance.

Reference is made to “detector” throughout the description, whereby a semiconductor detector, including any suitable detector, for example: a radiation detector, a photodetector, is meant.

The embodiments of the present disclosure require only minimal doping of semiconductor substrate. More specifically, in some embodiments no doping is needed to form the junction, as the junction is formed by an inducing layer. In other words, doping is only used for e.g. front and back contacts and guard contacts, whereby radiation does not pass through doped areas especially on the front side of the detector.

In the embodiments of the present disclosure, an inducing layer is used to induce electrons or holes on the silicon surface of the substrate. Such an induced charge passivates the silicon surface so that during the operation of the pin-diode, the depletion region will not reach the silicon-dielectric interface which would cause increased leakage current. The induced layer operates also as a cathode/anode in the detector. Guard rings are used to collect the current originating outside of the diode area.

Improved performance is beneficially achieved by the embodiments described herein. Compared to existing induced junction devices, this approach allows stronger inducing charges to be obtained, which leads to improved diode characteristics and performance. A low amount of material is present in the entrance window.

In the embodiments, a detector comprises a substrate. The substrate may be made of high resistivity semiconductor material. The substrate may be N- or P-type and have a planar surface, a textured surface or a combination of the two. Suitable semiconductor materials include Silicon, Germanium, III-V semiconductors, II-VI semiconductors (e.g. CdTe).

In the embodiments, a detector comprises an electric field generating layer on a first face of the substrate. The electric field generating layer is used to induce electrons or holes on the silicon surface. Such induced charge passivates the surface so that during the operation of the pin-diode, the depletion region will not reach the silicon-dielectric interface which would cause increased leakage current. The induced layer (induced charge layer) operates also as a cathode/anode in the detector. The electric field generating layer may comprise a patterned layer, or multiple patterned layers. In some embodiments, the layers may be of different materials. In some embodiments, a detector in accordance with the present disclosure is configured so that an electric field induced inversion layer is induced in the substrate by the electric field generating layer. When using a P-type substrate, this means that electrons appear in a very thin layer at the semiconductor-oxide interface, called an inversion layer because they are oppositely charged to the holes that prevail in the P-type material. In an N-type substrate, the inversion layer is formed in a similar way by holes. When an inversion layer forms, the depletion width ceases to expand with increase in the induced charge Q.

In some embodiments, the electric field generating layer comprises an electrically polarized material, such as a ferroelectric, ferroelectric, and/or electric material. A layer of non-ferroelectric dielectric material, such as SiO₂, may be present between the ferroelectric electric field generating layer and the substrate. A ferroelectric material has a spontaneous electric polarization that can be reversed by the application of an external electric field. Suitable materials include ScAIN (Scandium-doped aluminum nitride), HfZrO (hafnium zirconium oxide) and ferroelectric materials (including polymer foams which may consist of cellular polymer structure filled with air, for example the polymer may be polypropylene) and electric materials. An electric is a dielectric material that has a quasi-permanent electric charge or dipole polarisation. For example, a stack of silicon oxide and silicon nitride can be turned into a stable electric by charging the surface with a corona charge and annealing the layer afterwards. Charged electrics may also be produced by first heating the electric material and then cooling it in presence of strong electric field. This inducing charge is stable for decades or more. In addition, polymer materials can be used. Examples of suitable electric materials may comprise polymers (including fluoropolymers such as PTFE), or e.g. a stack of silicon oxide and silicon nitride). A benefit of using an electric material is, in addition to the exhibition of electric polarization, the ability to retain a static surface and/or volume charge of one or two polarities.

A benefit of using a ferroelectric, ferroelectric, and/or electric material is the ability to choose the polarity of the inducing charge by controlling the direction of the polarization during fabrication. Further, typical SiO2- or Al2O3-based implementations allow increasing the charge only based on deposition and heat treatment, whereby it is challenging to increase the inducing charge using only these limited methods. However, when using FE, ferroelectric, and/or electric materials, the charge can be controlled in an improved manner, as the charge may be controlled using an external electrical field and/or charge during the manufacturing process in addition to the deposition and/or heat treatment. In addition, use of the above-mentioned materials provides a range of options when considering radiation absorption, charge duration, charge stability, heat resistance, suitability for manufacturing process.

In some embodiments, the detector comprises a first electrical contact on the first face of the substrate and next to the electric field generating layer. The first face can be the so-called front or top face of the substrate.

In some embodiments, the detector comprises a second electrical contact on the second face of the substrate and opposite to the electric field generating layer. The second face can be the so-called back or bottom face of the substrate.

In some embodiments, the detector comprises one or more guard rails. Guard rails may be used to collect the current originating outside of the diode area. The front and back contact and guard metals may be any suitable material, e.g. aluminum.

In some embodiments, a detector in accordance with the present disclosure comprises a substrate having a having a resistivity value of 0.5 kΩcm or higher. For silicon, very good values are 10 kΩcm or higher.

In some embodiments, a detector in accordance with the present disclosure comprises at least one dopant, said dopant comprising at least one of the following materials: boron, aluminium, gallium, indium, phosphorus, arsenic, antimony, bismuth, lithium, silicon, germanium, nitrogen, gold, platinum, tellurium, sulphur, tin, beryllium, zinc, chromium, carbon, selenium, magnesium, chlorine, iodine, fluorine. The front contact and guard doping should be N-type doping if the substrate is P-type, and P-type doping if substrate is N-type. For the back contact and guard doping: P-type doping, if substrate is P-type and N-type doping if substrate is N-type.

In some embodiments, a detector in accordance with the present disclosure comprises or consists of an undoped substrate, which does not contain intentionally added impurities. Such a substrate may comprise or consist of pure semiconductor crystal, or a semiconductor crystal with naturally occurring doping originating from crystallographic defects such as vacancies.

In some embodiments, the detector comprises a first contact comprising a well and doping. Said first contact may be located around a dielectric layer of the electric field generating layer. In an embodiment, the first electrical contact surrounds the electrode insulator layer.

In some embodiments, the thickness of the substrate of the detector is from 200 nm to 50 mm, preferably from 1 μm to 5000 μm.

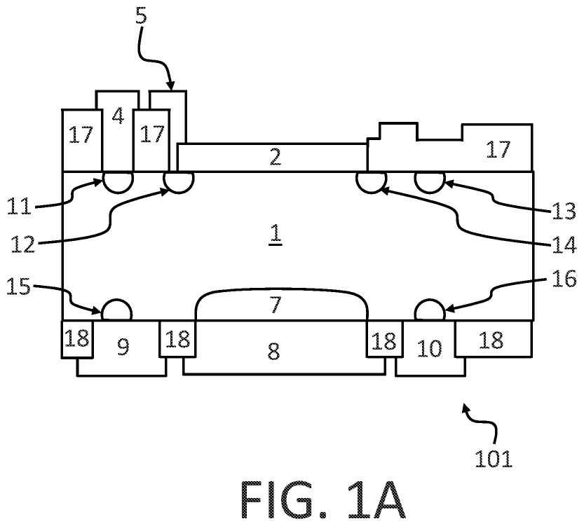

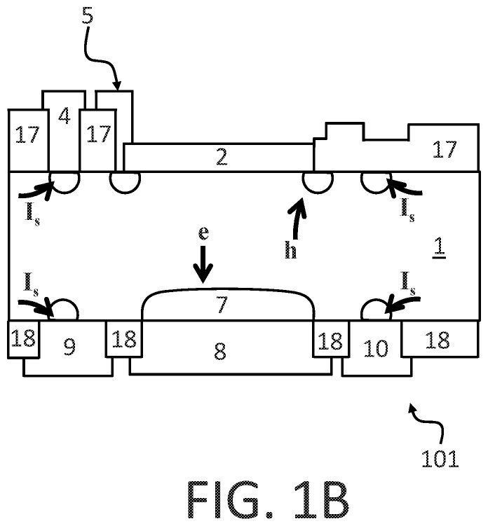

FIG. 1A illustrates a cross-section view of a detector 101 in accordance with at least some embodiments. The detector 101 comprises a substrate 1, an electric field generating layer (inducing layer) 2, a front guard contact (FGC) 4, a front contact 5, back contact doping 7, back contact 8, back guard contact (BGC) 9, and back guard contact 10. In addition, the detector 101 may comprise front guard doping (FGD) 11 and 13, front contact doping (FCD) 12 and 14, and back guard doping (BGD) 15 and 16, and front and back dielectrics 17 and 18.

FIG. 1B illustrates a cross-section view of exemplary embodiment of the detector 101 based on junction induced by electrically polarized material, where the flow of substrate and currents as well as electron holes have been illustrated in the case where the substrate is P-type, front contact doping is N-type, and the back contact doping is P-type. The radiation induced current flows between the back contact 8 and front contact 5 through the back contact doping 7, a portion of the substrate 1 and the front contact doping 12, 14. The portion of the substrate 1 comprises the electric field induced inversion layer in a surface layer of the substrate 1 (not shown). The portion of the substrate 1 further comprises the volume of the substrate 1 between the electric field induced inversion layer and the back contact doping 7, which volume comprises the depletion region. The front and back guards collect the substrate parasitic currents.

With respect to the terms used in the Figures, i.e. e, h, Iₛ; e is electron, h is hole, Iₛ is parasitic current from the semiconductor substrate, collected by the guard electrodes. V_{diode} is the voltage applied across the PN junction. V_{guard} is the voltage applied to the guard electrode.

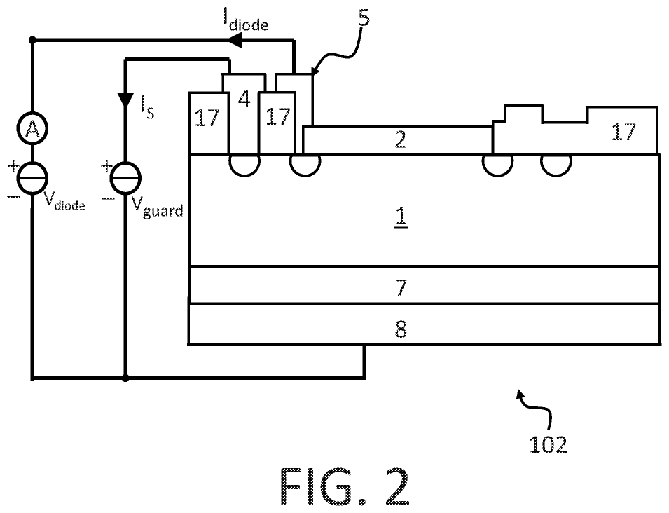

FIG. 2 illustrates a cross-section view of a semiconductor detector 102 based on junction induced by electrically polarized material, fabricated by single-sided processing, in accordance with at least some embodiments. Detector 102 is shown with P-type substrate, where front contact doping is N-type, and back contact doping is P-type.

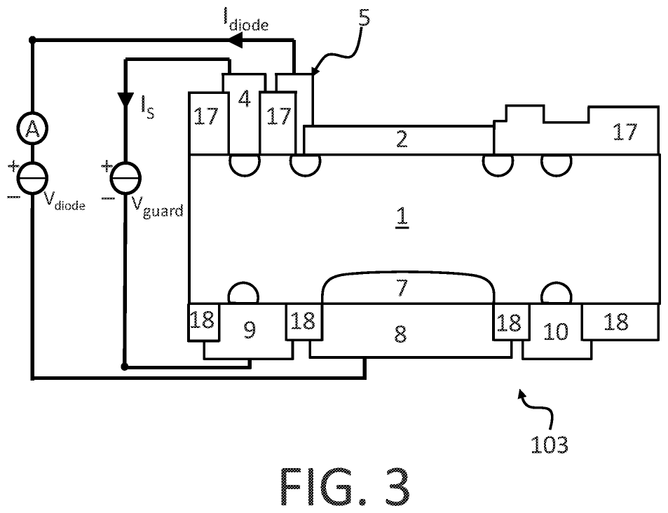

FIG. 3 illustrates a cross-section view of a detector 103 in accordance with at least some embodiments. The semiconductor detector 103 is based on junction induced by electrically polarized material, fabricated by double-sided processing. Detector 103 comprises a P-type substrate 1, where front contact doping is N-type, and back contact doping is P-type.

In a further embodiment, the detector has a N-type substrate, whereby the back contact is n-type, and the front contact is p-type.

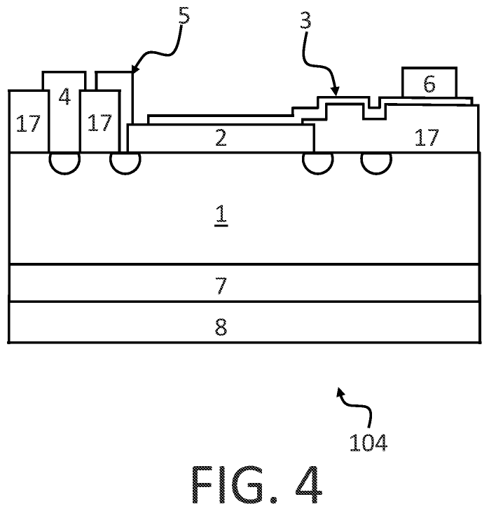

FIG. 4 shows an embodiment otherwise like the detector of FIG. 2 but provided with an inducing electrode 3 on the surface of the inducing layer 2 (dielectric layer of the electric field generating layer). Additionally, the detector 104 of FIG. 4 comprises a contact 6 for connecting a voltage to the inducing electrode 3. The inducing electrode is a thin layer of conducting material, preferably with a low attenuation coefficient for the radiation detected by the detector. In this configuration layer 2 can be leaky, i.e., some or all of the current can flow through it. The purpose of the inducing electrode is to apply a polarizing and/or charging voltage over inducing layer 2 when activating the detector. After the inducing layer 2 is polarized and/or charged, the detector does not anymore need the inducing electrode 3 for its operation. Therefore, the inducing electrode 3 should be as thin as practical. A preferable material for the inducing electrode 3 is graphene.

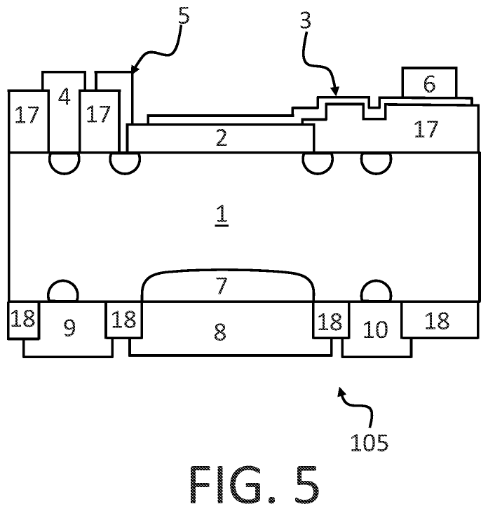

FIG. 5 shows an embodiment otherwise like the detector of FIG. 1A but provided with a inducing electrode 3 on the surface of the inducing layer 2 (dielectric layer of the electric field generating layer). Additionally, the detector 105 of FIG. 5 comprises a gate contact 6 for connecting a voltage to the inducing electrode 3. The purpose, structure and material of the inducing electrode 3 is the same as in the embodiment of FIG. 4.

The following combinations of materials may be employed in construction of the detectors disclosed herein, including the detectors shown in the Figures. A single combination of materials is disclosed on a single row:

| Detector | | |
|---|---|---|
| embodiment | Substrate | Inducing layer |
| 1 | N-type silicon | ZrHfO |
| 2 | N-type silicon | ScAlN |
| 3 | N-type silicon | Stack of SiO₂ and Si₃N₄ (SiNₓ) |
| 4 | N-type silicon | Polypropylene foam |
| 5 | N-type silicon | (Pb, La)(Zr, Ti)O₃ |
| 6 | P-type silicon | ZrHfO |
| 7 | P-type silicon | ScAlN |
| 8 | P-type silicon | Stack of SiO₂ and Si₃N₄ (SiNₓ) |
| 9 | P-type silicon | Polypropylene foam |
| 10 | P-type silicon | (Pb, La)(Zr, Ti)O₃ |
| 11 | N-type germanium | ZrHfO |
| 12 | N-type germanium | ScAlN |
| 13 | N-type germanium | Stack of SiO₂ and Si₃N₄ (SiNₓ) |
| 14 | N-type germanium | Polypropylene foam |
| 15 | N-type germanium | (Pb, La)(Zr, Ti)O₃ |
| 16 | P-type germanium | ZrHfO |
| 17 | P-type germanium | ScAlN |
| 18 | P-type germanium | Stack of SiO₂ and Si₃N₄ (SiNₓ) |
| 19 | P-type germanium | Polypropylene foam |
| 20 | P-type germanium | (Pb, La)(Zr, Ti)O₃ |

In the above embodiments 1-20, for example, the following dopants and contact metals may be used: substrate dopants in N-type silicon and germanium may comprise elements such as phosphorus, arsenic or antimony. Substrate dopants in P-type silicon and germanium may comprise elements such as boron and aluminum. The front and back dielectric may comprise SiO₂. Front contact metal, front guard contact metal, inducing electrode contact metal, back contact metal, and back guard contact metal may comprise metals such as aluminum, gold, titanium, wolfram, nickel, copper, molybdenum. The format (Pb,La) (Zr,Ti) O₃ is intended to mean PbZrO₃, PbTiO₃, LaZrO₃, or LaTiO₃. (SiNₓ) is intended to mean all stoichiometric forms of silicon and nitrogen. When charged e.g. via a corona discharge, a stack of SiO₂ and SiNₓ is an electric.

In some embodiments, the substrate of the detector comprises dopants such that the dopant concentration is less than 10¹⁵ dopant atoms per cm³, such as less than 10¹¹ dopant atoms per cm³, for example less than 10⁹ dopant atoms per cm³.

The above-mentioned embodiments are suitable for varying uses, e.g. a as radiation detection device or a photodetector. The present disclosure is suitable for use in and finds industrial applicability in at least the following: photodetectors in all spectral ranges: single pixels and imaging array (vast amount of applications from cameras to light level sensors etc.), detection of UV: Solar blind UV detectors, Military applications: detecting a flash from the firing of a weapon or explosive, X-rays: Wide range of medical applications: Computer tomography (CT), dental X-ray, etc., material analysis, structural monitoring, X-ray customs inspections (i.e. non-intrusive inspections). Further, at least some embodiments are sensitive to radiation such as alpha, beta, gamma radiation, and particle radiation, which is beneficial for safety and monitoring applications.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

REFERENCE SIGNS LIST

| | |
|---|---|
| 101, 102, 103, 104, 105 | Semiconductor detector |
| 1 | Substrate |
| 2 | Inducing layer |
| 3 | Inducing electrode |
| 4 | Front guard contact |
| 5 | Front contact |
| 6 | Contact to inducing electrode |
| 7 | Back contact doping |
| 8 | Back contact |
| 9, 10 | Back guard contact |
| 11, 13 | Front guard doping |
| 12, 14 | Front contact doping |
| 15, 16 | Back guard doping |
| 17 | Front dielectric |
| 18 | Back dielectric |

1. A radiation detector, comprising:
a substrate made of semiconductor material;
an electric field generating layer on a first face of the substrate, the electric field generating layer inducing electric field into the substrate for forming an inversion layer in the substrate;
a first electrical contact on the first face of the substrate and next to the electric field generating layer; and
a second electrical contact on the second face of the substrate and opposite to the electric field generating layer;
wherein the electric field generating layer comprises a dielectric layer with a polarization and/or charge for inducing the electric field, wherein the dielectric layer comprises at least one of: ferroelectric material, electric material, ferroelectric material.

2. (canceled)

3. (canceled)

4. The radiation detector of claim 1, wherein:
the electric field generating layer comprises an electric material.

5. The radiation detector of claim 1, wherein:
the electric field generating layer comprises a ferroelectric material.

6. (canceled)

7. (canceled)

8. The radiation detector of claim 1, wherein:
the detector comprises an inducing electrode on the electric field generating layer for polarizing the dielectric layer.

9. The radiation detector of claim 1, wherein:
the detector comprises an inducing electrode on the electric field generating layer for charging the dielectric layer.

10. The radiation detector of claim 8, wherein:
the inducing electrode is formed by a layer of graphene.

11. The radiation detector of claim 8, wherein:
the electric field generating layer is leaky such that a current can flow between the inducing electrode and the substrate through the electric field generating layer.

12. The radiation detector of claim 1, wherein:
the resistivity of the substrate is more than 10 kΩcm.

13. (canceled)

14. The radiation detector of claim 1, wherein:
the first electrical contact comprises contact doping in the substrate.

15. The radiation detector of claim 1, wherein:
the first electrical contact comprises a front contact doping well in the substrate; and
the detector is configured so that a current flow path is formed between the electric field induced inversion layer and the front contact doping well for conducting the radiation induced current.

16. The radiation detector of claim 1, wherein:
the first electrical contact is located around the electrode insulator layer.

17. (canceled)

18. (canceled)

19. A radiation detector, comprising:
a substrate made of semiconductor material;
an electric field generating layer on a first face of the substrate, the electric field generating layer comprising a dielectric layer with a charge for inducing an electric field into the substrate for forming an inversion layer in the substrate, wherein the dielectric layer comprises at least one of: electric material, ferroelectric material;
a first electrical contact on the first face of the substrate around to the electric field generating layer; and
a second electrical contact on the second face of the substrate and opposite to the electric field generating layer.

20. The radiation detector of claim 19, wherein:
the first electrical contact surrounds the electric field generating layer.

21. The radiation detector of claim 20, wherein:
the first electrical contact comprises a contact doping well in the substrate.

22. The radiation detector of claim 4, wherein the electric material comprises a polymer or a stack of silicon oxide and silicon nitride.

23. The radiation detector of claim 5, wherein the ferroelectric material comprises a polymer foam comprising a cellular polymer structure filled with air.

24. The radiation detector of claim 19, wherein the dielectric layer comprises a stack of silicon oxide and silicon nitride.

25. The radiation detector of claim 19, wherein the dielectric layer comprises polypropylene foam.
